(19) United States
(12) Patent Application Publication
(10) Pub. No.: US 2025/0063751 A1
(43) Pub. Date: Feb. 20, 2025

(54) MANUFACTURING METHOD FOR SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP)

(73) Assignee: Japan Display Inc., Tokyo (JP)

(21) Appl. No.: 18/934,519

(22) Filed: Nov. 1, 2024

Related U.S. Application Data
(63) Continuation of application No. PCT/JP2023/010846, filed on Mar. 20, 2023.

(30) Foreign Application Priority Data
May 19, 2022 (JP) 2022-082314

(51) Int. Cl. H01L 29/66; H01L 21/02

(52) U.S. Cl. CPC H01L 29/66742; H01L 21/02565; H01L 21/02631

(57) ABSTRACT

A method for manufacturing a semiconductor device comprises steps of: forming an oxide semiconductor layer on a substrate by a sputtering method; performing a first heat treatment on the oxide semiconductor layer after placing the substrate on which the oxide semiconductor layer is formed in a heating furnace having a heating medium maintained at a preset temperature; forming a gate insulating layer on the oxide semiconductor layer after the first heat treatment; and forming a gate electrode on the gate insulating layer. When the substrate is installed in the heating furnace, a temperature drop of the heating medium is kept within 15% of the set temperature.

### CROSS REFERENCE TO RELATED APPLICATIONS

This application is a Continuation of International Patent Application No. PCT/JP2023/010846, filed on Mar. 20, 2023, which claims the benefit of priority to Japanese Patent Application No. 2022-082314, filed on May 19, 2022, the entire contents of which are incorporated herein by reference.

### FIELD

An embodiment of the present invention relates to a method for manufacturing a semiconductor device. In particular, an embodiment of the present invention relates to a method for manufacturing a semiconductor device in which an oxide semiconductor is used as a channel.

### BACKGROUND

In recent years, a semiconductor device in which an oxide semiconductor is used for a channel instead of amorphous silicon, polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher field-effect mobility than the semiconductor device in which amorphous silicon is used for the channel.

### SUMMARY

A method for manufacturing a semiconductor device according to an embodiment of the present invention comprises the steps of: forming an oxide semiconductor layer on a substrate by a sputtering method; performing a first heat treatment on the oxide semiconductor layer after placing the substrate on which the oxide semiconductor layer is formed in a heating furnace having a heating medium maintained at a preset temperature; forming a gate insulating layer on the oxide semiconductor layer after the first heat treatment; and forming a gate electrode on the gate insulating layer. When the substrate is installed in the heating furnace, a temperature drop of the heating medium is kept within 15% of the preset temperature.

A method for manufacturing a semiconductor device according to an embodiment of the present invention comprises the steps of: forming a gate electrode on a substrate; forming a gate insulating layer on the gate electrode; forming an oxide semiconductor layer on the gate insulating layer by a sputtering method; and performing a first heat treatment on the oxide semiconductor layer after placing the substrate on which the oxide semiconductor layer is formed in a heating furnace having a heating medium maintained at a preset temperature. When the substrate is installed in the heating furnace, a temperature drop of the heating medium is kept within 15% of the preset temperature.

### BRIEF DESCRIPTION OF THE DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a sequence diagram showing a method for manufacturing a semiconductor device according to an embodiment of the present invention.

FIG. 14 is a sequence diagram showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a plan view showing an outline of a display device according to an embodiment of the present invention.

FIG. 19 is a block diagram showing a circuit configuration of a display device according to an embodiment of the present invention.

FIG. 20 is a circuit diagram showing a pixel circuit of a display device according to an embodiment of the present invention.

FIG. 21 is a cross-sectional view showing an outline of a display device according to an embodiment of the present invention.

FIG. 22 is a plan view of a pixel electrode and a common electrode of a display device according to an embodiment of the present invention.

FIG. 23 is a circuit diagram showing a pixel circuit of a display device according to an embodiment of the present invention.

FIG. 24 is a cross-sectional view showing an outline of a display device according to an embodiment of the present invention.

FIG. 25 is a graph showing a temperature rise during OS annealing of an oxide semiconductor layer in a method for manufacturing a semiconductor device according to an embodiment of the present invention.

FIG. 26 is a diagram showing the electrical characteristics (Id-Vg characteristics) of a semiconductor device according to an embodiment of the present invention.

FIG. 27 is a diagram showing the electrical characteristics (Id-Vg characteristics) of a semiconductor device according to an embodiment of the present invention.

FIG. 28 is a diagram showing the electrical characteristics (Id-Vg characteristics) of a semiconductor device according to an embodiment of the present invention.

FIG. 29 is a diagram showing the electrical characteristics of semiconductor devices when OS annealing is performed under different conditions.

FIG. 30 is a diagram showing the electrical characteristics of semiconductor devices when OS annealing is performed under different conditions.

### DESCRIPTION OF EMBODIMENTS

Any of an amorphous semiconductor and a semiconductor having crystallinity can be used as an oxide semiconductor. In particular, the semiconductor having crystallinity has an advantage that an oxygen vacancy is less likely to be formed than the amorphous semiconductor. Therefore, in recent years, attention has been paid to developing a semiconductor device using the oxide semiconductor having crystallinity. Processing for forming an oxide semiconductor having good crystallinity has been rapidly established because the semiconductor device using the oxide semiconductor having crystallinity greatly changes in properties depending on the crystallinity of a channel portion.

An object of an embodiment of the present invention is to provide a method for manufacturing a semiconductor device with high reliability and field-effect mobility.

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same elements as those described previously with reference to the preceding drawings, and a detailed description thereof may be omitted as appropriate.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a reverse direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer and an organic EL display device including an organic EL layer as the display device, the structure in the present embodiment can be applied to a display device including the other electro-optic layers described above.

The expressions “a includes A, B, or C”, “a includes any of A, B, and C”, and “a includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

### First Embodiment

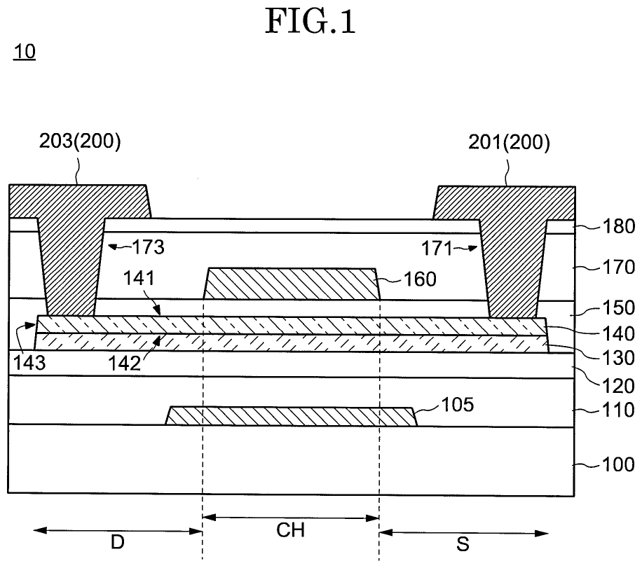

A semiconductor device according to an embodiment of the present invention will be described with reference to FIG. 1 to FIG. 11. For example, a semiconductor device of the embodiment described below may be a transistor used in an integrated circuit (IC) such as a micro-processing unit (MPU) or a memory circuit in addition to a transistor used in a display device.

### [Configuration of Semiconductor Device 10]

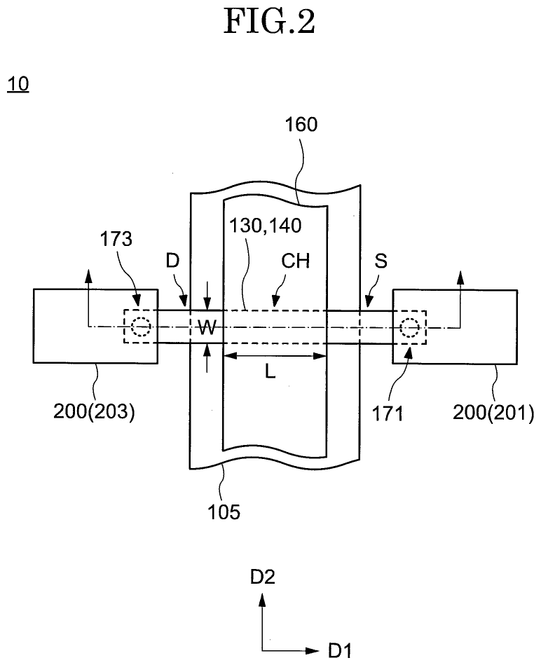

A configuration of a semiconductor device according to an embodiment of the present invention will be described with reference to FIG. 1 and FIG. 2. FIG. 1 is a cross-sectional view showing an outline of a semiconductor device 10 according to an embodiment of the present invention. FIG. 2 is a plan view showing an outline of the semiconductor device 10 according to an embodiment of the present invention.

As shown in FIG. 1, the semiconductor device 10 is arranged above a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. In the case where the source electrode 201 and the drain electrode 203 are not distinguished from each other, they may be collectively referred to as a source/drain electrode 200.

The gate electrode 105 is arranged on the substrate 100. The gate insulating layer 110 and the gate insulating layer 120 are arranged on the substrate 100 and the gate electrode 105. The metal oxide layer 130 is arranged on the gate insulating layer 120. The metal oxide layer 130 is in contact with the gate insulating layer 120. The oxide semiconductor layer 140 is arranged on the metal oxide layer 130. The oxide semiconductor layer 140 is in contact with the metal oxide layer 130. Among the main surface of the oxide semiconductor layer 140, the surface in contact with the metal oxide layer 130 is referred to as a bottom surface 142. An end portion of the metal oxide layer 130 is substantially the same as an end portion of the oxide semiconductor layer 140.

In the present embodiment, no semiconductor layer or oxide semiconductor layer is arranged between the metal oxide layer 130 and the substrate 100.

In the present embodiment, although a configuration in which the metal oxide layer 130 is in contact with the gate insulating layer 120 and the oxide semiconductor layer 140 is in contact with the metal oxide layer 130 is exemplified, the configuration is not limited to this configuration. Other layers may be arranged between the gate insulating layer 120 and the metal oxide layer 130. Other layers may be arranged between the metal oxide layer 130 and the oxide semiconductor layer 140.

In FIG. 1, although the side surfaces of the metal oxide layer 130 and the side surfaces of the oxide semiconductor layer 140 are arranged in a straight line, the configuration is not limited to this configuration. The angle of the side surfaces of the metal oxide layer 130 with respect to the main surface of the substrate 100 may be different from the angle of the side surfaces of the oxide semiconductor layer 140. The cross-sectional shape of the side surfaces of at least one of the metal oxide layer 130 and the oxide semiconductor layer 140 may be curved.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. Among the main surface of the oxide semiconductor layer 140, the surface in contact with the gate insulating layer 150 is referred to as a top surface 141. A surface between the top surface 141 and the bottom surface 142 is referred to as a side surface 143. The insulating layers 170 and 180 are arranged on the gate insulating layer 150 and the gate electrode 160. Openings 171 and 173 that reach the oxide semiconductor layer 140 are arranged in the insulating layers 170 and 180, respectively. The source electrode 201 is arranged inside the opening 171. The source electrode 201 is in contact with the oxide semiconductor layer 140 at the bottom of the opening 171. The drain electrode 203 is arranged inside the opening 173. The drain electrode 203 is in contact with the oxide semiconductor layer 140 at the bottom of the opening 173.

The gate electrode 105 has a function as a bottom gate of the semiconductor device 10 and a function as a light-shielding film for the oxide semiconductor layer 140. The gate insulating layer 110 functions as a barrier film that shields impurities that diffuse from the substrate 100 toward the oxide semiconductor layer 140. The gate insulating layers 110 and 120 have a function as a gate insulating layer for the bottom gate. The metal oxide layer 130 is a layer containing a metal oxide containing aluminum as a main component, and has a function as a gas barrier film for shielding a gas such as oxygen or hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and that is closer to the drain electrode 203 than the channel region CH. The oxide semiconductor layer 140 in the channel region CH has the physical properties of a semiconductor. The oxide semiconductor layer 140 in the source region S and the drain region D has the physical properties as a conductor.

The gate electrode 160 has a function as a light-shielding film for a top gate and the oxide semiconductor layer 140 of the semiconductor device 10. The gate insulating layer 150 has a function as a gate insulating layer for the top gate, and also has a function of releasing oxygen by a heat treatment in a manufacturing process. The insulating layers 170 and 180 have a function of insulating the gate electrode 160 and the source/drain electrode 200 and reducing parasitic capacitance therebetween. The operation of the semiconductor device 10 is controlled mainly by a voltage supplied to the gate electrode 160. An auxiliary voltage is supplied to the gate electrode 105. However, in the case where the gate electrode 105 is simply used as a light-shielding film, the gate electrode 105 may be floated without supplying a particular voltage. In other words, the gate electrode 105 may be simply “light-shielding film”.

In the present embodiment, although a dual-gate transistor in which a gate electrode is arranged both above and below the oxide semiconductor layer is exemplified as the semiconductor device 10, the configuration is not limited to this configuration. For example, the semiconductor device 10 may be a bottom-gate transistor in which the gate electrode is arranged only below the oxide semiconductor layer, or a top-gate transistor in which the gate electrode is arranged only above the oxide semiconductor layer. The above configuration is merely an embodiment, and the present invention is not limited to the above configuration.

As shown in FIG. 2, in a plan view, a planar pattern of the metal oxide layer 130 is substantially the same as a planar pattern of the oxide semiconductor layer 140. Referring to FIG. 1 and FIG. 2, the bottom surface 142 of the oxide semiconductor layer 140 is covered with the metal oxide layer 130. In particular, in the present embodiment, all of the bottom surface 142 of the oxide semiconductor layer 140 is covered with the metal oxide layer 130. In a direction D1, a width of the gate electrode 105 is greater than a width of the gate electrode 160. The direction D1 is a direction connecting the source electrode 201 and the drain electrode 203, and is a direction indicating a channel length L of the semiconductor device 10. Specifically, a length of a region (the channel region CH) where the oxide semiconductor layer 140 overlaps the gate electrode 160 in the direction D1 is the channel length L, and a width of the channel region CH in a direction D2 is a channel width W.

In the present embodiment, although a configuration in which all of the bottom surface 142 of the oxide semiconductor layer 140 is covered with the metal oxide layer 130 is exemplified, the present invention is not limited to this configuration. For example, part of the bottom surface 142 of the oxide semiconductor layer 140 may not be in contact with the metal oxide layer 130. For example, all of the bottom surface 142 of the oxide semiconductor layer 140 in the channel region CH may be covered with the metal oxide layer 130, and all or part of the bottom surface 142 of the oxide semiconductor layer 140 in the source region S and the drain region D may not be covered with the metal oxide layer 130. That is, all or a part of the bottom surface 142 of the oxide semiconductor layer 140 in the source region S and the drain region D may not be in contact with the metal oxide layer 130. However, in the above configuration, part of the bottom surface 142 of the oxide semiconductor layer 140 in the channel region CH may not be covered with the metal oxide layer 130, and other parts of the bottom surface 142 may be in contact with the metal oxide layer 130.

In the present embodiment, although a configuration in which the gate insulating layer 150 is formed on the entire surface, and the openings 171 and 173 are arranged in the gate insulating layer 150 is exemplified, the configuration is not limited to this configuration. That is, the gate insulating layer 150 may be patterned into a shape different from the shape shown in FIG. 1. For example, the gate insulating layer 150 may be patterned to expose all or part of the oxide semiconductor layer 140 in the source region S and the drain region D. That is, the gate insulating layer 150 of the source region S and the drain region D may be removed, and the oxide semiconductor layer 140 and the insulating layer 170 may be in contact with each other in these regions.

Although a configuration in which the source/drain electrode 200 does not overlap the gate electrode 105 and the gate electrode 160 is exemplified in FIG. 2 in a plan view, the configuration is not limited to this configuration. For example, in a plan view, the source/drain electrode 200 may overlap at least one of the gate electrode 105 and the gate electrode 160. The above configuration is merely an embodiment, and the present invention is not limited to the above configuration.

### [Materials of Each Member of Semiconductor Device 10]

A rigid substrate having light transmittance such as a glass substrate, a quartz substrate, a sapphire substrate, or the like is used as the substrate 100. In the case where the substrate 100 needs to be flexible, a substrate containing a resin such as a polyimide substrate, an acryl substrate, a siloxane substrate, or a fluororesin substrate is used as the substrate 100. In the case where the substrate containing a resin is used as the substrate 100, an impurity may be introduced into the above resin in order to improve the heat resistance of the substrate 100. In particular, in the case where the semiconductor device 10 is a top-emission display, since the substrate 100 does not need to be transparent, an impurity that deteriorates the transparency of the substrate 100 may be used. In the case where the display device 10 is used as an integrated circuit other than the display device, a semiconductor substrate such as a silicon substrate, a silicon carbide substrate, and a compound semiconductor substrate, or a conductive substrate such as a stainless substrate may be used as the substrate 100.

Common metal materials are used as the gate electrode 105, the gate electrode 160, and the source/drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof are used as these members. The above-described materials may be used in a single layer or stacked layer as the gate electrode 105, the gate electrode 160, and the source/drain electrode 200.

Common insulating materials are used as the gate insulating layers 110 and 120 and the insulating layers 170 and 180. For example, an inorganic insulating layer such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) is used as the insulating layer.

Among the above-described insulating layer, an insulating layer containing oxygen is used as the gate insulating layer 150. For example, an inorganic insulating layer such as silicon oxide (SiOₓ), silicon oxynitride (SiOₓN_{y}), aluminum oxide (AlOₓ), or aluminum oxynitride (AlOₓN_{y}) is used as the gate insulating layer 150.

An insulating layer having a function of releasing oxygen by the heat treatment is used as the gate insulating layer 120. For example, a temperature of the heat treatment at which the gate insulating layer 120 releases oxygen is 600° C. or lower, 500° C. or lower, 450° C. or lower, or 400° C. or lower. That is, for example, the gate insulating layer 120 releases oxygen at the temperature of the heat treatment performed in the manufacturing process of the semiconductor device 10 when the glass substrate is used as the substrate 100.

An insulating layer with few defects is used as the gate insulating layer 150. For example, in the case where a composition ratio of oxygen in the gate insulating layer 150 is compared with a composition ratio of oxygen in the insulating layer having a composition similar to that of the gate insulating layer 150 (hereinafter referred to as “another insulating layer”), the composition ratio of oxygen in the gate insulating layer 150 is closer to the stoichiometric ratio with respect to the insulating layer than the composition ratio of oxygen in the another insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by an electron-spin resonance method (ESR) may be used as the gate insulating layer 150.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

A metal oxide containing aluminum as a main component is used as the metal oxide layer 130. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 130. The “metal oxide layer containing aluminum as a main component” means that the proportion of aluminum contained in the metal oxide layer 130 is 1% or more of the entire metal oxide layer 130. The proportion of aluminum contained in the metal oxide layer 130 may be 5% or more and 70% or less, 10% or more and 60% or less, or 30% or more and 50% or less of the entire metal oxide layer 130. The ratio may be a mass ratio or a weight ratio.

A metal oxide with semiconductor properties may be used as the oxide semiconductor layer 140. For example, an oxide semiconductor containing two or more metals including indium (In) is used as the oxide semiconductor layer 140. The proportion of indium in the entire oxide semiconductor layer 140 is 50% or more. Gallium (Ga), zinc (Zn), aluminum (Al), hafnium (Hf), yttrium (Y), zirconia (Zr), and lanthanoids are used as the oxide semiconductor layer 140 in addition to indium. Elements other than those described above may be used as the oxide semiconductor layer 140.

In the present embodiment, the oxide semiconductor layer 140 has a polycrystalline structure. That is, the oxide semiconductor layer 140 of the present embodiment is composed of an oxide semiconductor formed using a poly-OS (Poly-crystalline Oxide Semiconductor) technique. The Poly-OS technique refers to a technique of forming an oxide semiconductor layer having a polycrystalline structure. In the present embodiment, as will be described later, the oxide semiconductor layer 140 is crystallized by performing the heat treatment on the oxide semiconductor layer 140 formed by a sputtering method.

In the oxide semiconductor layer 140 of the present embodiment, since the indium ratio is 50% or more, an oxygen vacancy is likely to be formed. On the other hand, in the oxide semiconductor having crystallinity, the oxygen vacancy is less likely to be formed than in the amorphous oxide semiconductor. Therefore, the oxide semiconductor layer 140 has an advantage that the oxygen vacancy is hardly formed even though the indium ratio is 50% or more.

### [Method for Manufacturing Semiconductor Device 10]

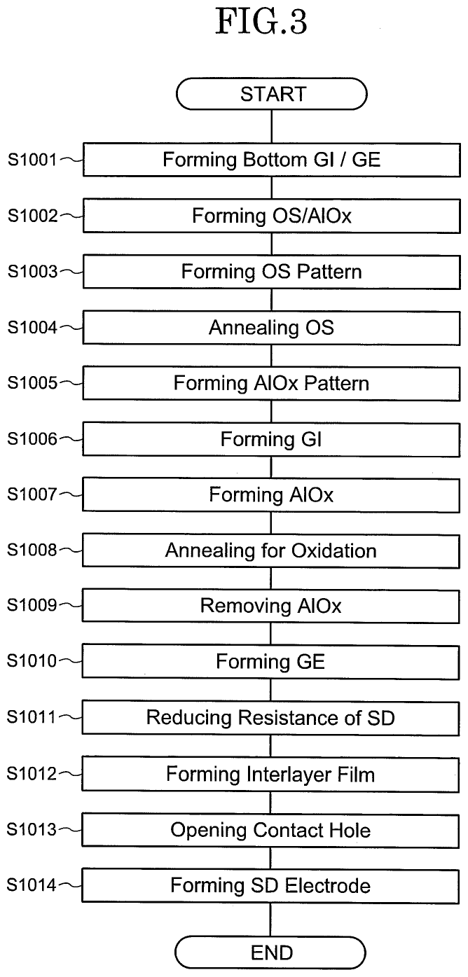

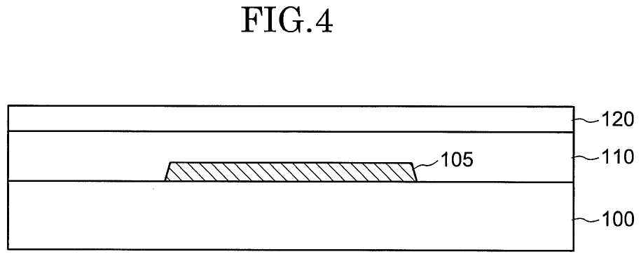

A method for manufacturing the semiconductor device 10 according to an embodiment of the present invention will be described with reference to FIG. 3 to FIG. 11. FIG. 3 is a sequence diagram showing a method for manufacturing the semiconductor device 10 according to an embodiment of the present invention. FIG. 4 to FIG. 11 are cross-sectional views showing a method for manufacturing the semiconductor device 10 according to an embodiment of the present invention. In the following description of the manufacturing method, a method of manufacturing the semiconductor device 10 in which aluminum oxide is used as the metal oxide layer 130 will be described.

As shown in FIG. 3 and FIG. 4, the gate electrode 105 is formed as the bottom gate on the substrate 100, and the gate insulating layers 110 and 120 are formed on the gate electrode 105 (step S1001 of FIG. 3). For example, silicon nitride is formed as the gate insulating layer 110. For example, silicon oxide is formed as the gate insulating layer 120. The gate insulating layer 110 and 120 are formed by a CVD (Chemical Vapor Deposition) method. In the present specification, performing deposition on a substrate by a method such as a sputtering method or a CVD method is expressed as “forming a thin film”, but used in the same meaning as the expression “depositing a thin film”.

For example, the use of silicon nitride as the gate insulating layer 110 allows the gate insulating layer 110 to block impurities that diffuse from the substrate 100 toward the oxide semiconductor layer 140. The silicon oxide used as the gate insulating layer 120 is silicon oxide having a physical property of releasing oxygen by the heat treatment.

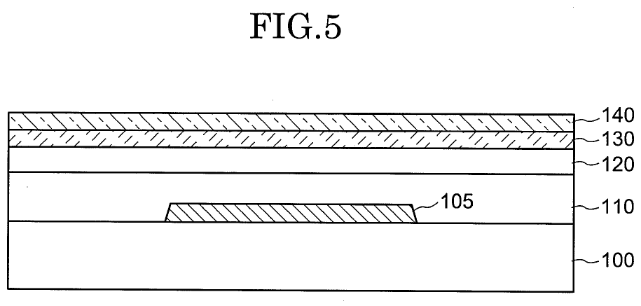

As shown in FIG. 3 and FIG. 5, the metal oxide layer 130 and the oxide semiconductor layer 140 are formed on the gate insulating layer 120 (step S1002 in FIG. 3). In the present embodiment, the metal oxide layer 130 and the oxide semiconductor layer 140 are formed by the sputtering method. In particular, the oxide semiconductor layer 140 is formed by sputtering using a target formed of an oxide semiconductor having crystallinity.

For example, a thickness of the metal oxide layer 130 is 1 nm or more and 100 nm or less, 1 nm or more and 50 nm or less, 1 nm or more and 30 nm or less, or 1 nm or more and 10 nm or less. In the present embodiment, aluminum oxide is used as the metal oxide layer 130. Aluminum oxide has a high barrier property against gas.

In the present embodiment, the aluminum oxide used as the metal oxide layer 130 blocks hydrogen and oxygen released from the gate insulating layer 120, and suppresses the released hydrogen and oxygen from reaching the oxide semiconductor layer 140.

In the oxide semiconductor layer 140 of the present embodiment, since the indium ratio is 50% or more as described above, the semiconductor device 10 with high mobility can be realized, but oxygen is easily reduced, and oxygen vacancies are easily formed in the layer. Therefore, it is preferable to block the hydrogen released from the gate insulating layer 120 by the metal oxide layer 130 in order to suppress the reduction of the oxide semiconductor layer 140.

In addition, after the oxide semiconductor layer 140 is formed, more oxygen vacancies are formed on the upper layer side of the oxide semiconductor layer 140 than on the lower layer side in various manufacturing processes (patterning process or etching process). That is, the oxygen vacancies in the oxide semiconductor layer 140 are distributed non-uniformly in a thickness direction. In this case, if a sufficient amount of oxygen is supplied to repair the oxygen vacancies formed on the upper layer side of the oxide semiconductor layer 140, excessive oxygen is supplied to the lower layer side of the oxide semiconductor layer 140. As a result, the excessively supplied oxygen forms a defect level different from the oxygen vacancy, which may lead to a phenomenon such as characteristic fluctuations in a reliability test or a decrease in field-effect mobility. Therefore, blocking the oxygen released from the gate insulating layer 120 by the metal oxide layer 130 is also preferable in order to suppress excessive oxygen supply to the lower layer side of the oxide semiconductor layer 140.

For example, a thickness of the oxide semiconductor layer 140 is 10 nm or more and 100 nm or less, 15 nm or more and 70 nm or less, or 20 nm or more and 40 nm or less. The oxide semiconductor layer 140 before the heat treatment (OS annealing) described later is amorphous.

When the oxide semiconductor layer 140 is crystallized by the OS annealing described later, the oxide semiconductor layer 140 before the OS annealing is preferably amorphous (a state in which the oxide semiconductor has few crystalline components). That is, a condition for forming the oxide semiconductor layer 140 is preferably a condition such that the oxide semiconductor layer 140 immediately after forming does not crystallize as much as possible. For example, in the case where the oxide semiconductor layer 140 is formed by the sputtering method, it is desirable to form the oxide semiconductor layer 140 while controlling a temperature of an object to be formed (including the substrate 100 and the structure formed thereon). In addition, the object to be temperature controlled is the structure on the substrate 100, but since the structure formed on the substrate 100 is very thin, it may be considered that the temperature of the substrate 100 is substantially controlled. Therefore, in the following explanation, the object to be formed (that is, the structure on the substrate 100) may be simply referred to as “substrate”.

When the substrate is subjected to a thin film formation (deposition) by the sputtering method, ions generated in the plasma and atoms recoiled by a sputtering target collide with the object to be formed (specifically, the structure formed on the substrate 100), so that the temperature of the substrate increases in the thin film forming process. When the temperature of the substrate increases in the thin film forming process, the oxide semiconductor layer 140 contains microcrystals immediately after the formation, and crystallization due to subsequent OS annealing is inhibited.

In order to control the temperature of the substrate (hereinafter, referred to as “deposition temperature”) at the time of forming the oxide semiconductor layer 140, for example, the thin film can be formed while the substrate is cooled. For example, the substrate can be cooled from the other side of the surface to be formed so that the deposition temperature may be 100° C. or lower, 70° C. or lower, 50° C. or lower, or 30° C. or lower. In particular, the deposition temperature of the oxide semiconductor layer 140 of the present embodiment is preferably 50° C. or lower. In the present embodiment, the oxide semiconductor layer 140 is formed at a deposition temperature of 50° C. or lower, and the OS annealing, which will be described later, is performed at a heating temperature of 400° C. or higher. As described above, in the present embodiment, it is preferable that the difference between the temperature at the time of forming the oxide semiconductor layer 140 and the temperature at the time of performing the OS annealing on the oxide semiconductor layer 140 is 350° C. or higher. By forming the oxide semiconductor layer 140 while the substrate is cooled, it is possible to obtain the oxide semiconductor layer 140 with few crystalline components immediately after the formation.

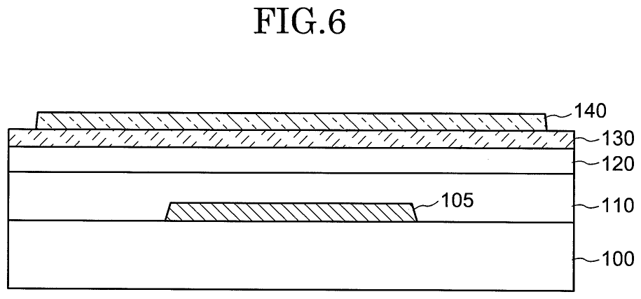

Next, as shown in FIG. 3 and FIG. 6, a pattern (OS pattern) composed of the oxide semiconductor layer 140 is formed (step S1003 in FIG. 3). Although not shown, a resist mask is formed on the oxide semiconductor layer 140, and the oxide semiconductor layer 140 is etched using the resist mask. Etching of the oxide semiconductor layer 140 may be performed by wet etching or dry etching. For example, an acidic etchant can be used in the wet etching. Specifically, oxalic acid or hydrofluoric acid can be used as the etchant.

After patterning the oxide semiconductor layer 140, the heat treatment (OS annealing) is performed on the oxide semiconductor layer 140 (step S1004 in FIG. 3). In the OS annealing, the oxide semiconductor layer 140 in an amorphous state is crystallized by performing a heat treatment on the oxide semiconductor layer 140 at a temperature of 400° C. or higher and 450° C. or lower in an air atmosphere. The heating atmosphere is not limited to the air atmosphere, but is preferably an oxidizing atmosphere (an atmosphere containing oxygen). More preferably, the oxidizing atmosphere is a wet atmosphere containing water vapor (specifically, a moist air atmosphere). In addition, the treatment time of the heat treatment may be 60 minutes or more, and may be 60 minutes or more and 90 minutes or less.

In the present embodiment, the substrate on which the patterned oxide semiconductor layer 140 is formed is put into a heating furnace having a heating medium (in the present embodiment, a support plate) maintained at a preset temperature (400° C. or higher and 450° C. or lower). In the present embodiment, the set temperature of the heating medium is 400° C. The support plate as the heating medium has a function of supporting the substrate and a function of heating the substrate and the thin film (including the oxide semiconductor layer 140) formed on the substrate. When the substrate on which the oxide semiconductor layer 140 is formed is placed on the support plate, the oxide semiconductor layer 140 is rapidly heated.

Here, in the present embodiment, when the substrate is placed in the heating furnace, the temperature drop of the support plate is suppressed to within 15%, within 10%, or within 5% of the set temperature. That is, in the present embodiment, the temperature of the support plate is controlled so that the oxide semiconductor layer 140 reaches the set temperature in as short a time as possible when the OS annealing is performed on the oxide semiconductor layer 140. As described above, in the present embodiment, the heat treatment (specifically, furnace annealing) that involves rapid temperature rise is performed on the oxide semiconductor layer 140.

As described above, in order to prevent the temperature drop of the support plate, it is preferable to create an environment in which the support plate of the heating furnace does not contact the room temperature atmosphere as much as possible. For example, by using a tubular heating furnace having a certain depth and installing the support plate at a position far from the furnace opening to be opened to the atmosphere, it is possible to prevent a decrease in the set temperature of the support plate. In addition, arranging a preliminary chamber in front of the heating furnace and setting the set temperature of the preliminary chamber to a temperature of 350° C. or higher and 450° C. or lower (preferably, the same temperature as the set temperature of the heating furnace) makes it possible to prevent the temperature drop of the support plate in the heating furnace. In this case, when the substrate is put into the furnace, the substrate is put into the furnace without staying in the substrate in the preliminary chamber. This is to prevent the temperature of the substrate from rising in the preliminary chamber.

Although the above measures focus on preventing the temperature drop of the support plate due to a decrease in the inner temperature (ambient temperature) of the heating furnace, it is also preferable to suppress the direct temperature drop of the support plate due to the installation of the substrate. For example, by making the heat capacity of the support plate as large as possible, it is possible to suppress the decrease in the temperature of the support plate when contacting the substrate. For example, the substrate can be pre-heated before installation of the substrate on the support plate. In this case, the pre-heating set temperature (heating temperature) is preferably within a temperature range in which crystallization of the oxide semiconductor layer 140 does not start. The reason why the pre-heating temperature is set to the above-described temperature range is to suppress microcrystals from being formed inside the oxide semiconductor layer 140 before the actual OS annealing.

In addition, when the substrate is placed on the support plate, the temperature of the support plate may be temporarily increased to a temperature of 15%, 10%, or 5% higher. That is, the temperature of the support plate can be set to be higher in advance in anticipation of the temperature drop of the support plate caused by the installation of the substrate. In this case, by returning the set temperature of the support plate to a predetermined set temperature (in the present embodiment, 400° C.) at the timing when the substrate is installed, it is possible to shorten the time until the substrate reaches the heating temperature. In addition, it is also possible to divide the support plate into blocks and set the temperature for each block. In this case, the temperature of the entire support plate may be collectively controlled, or may be individually controlled for each block. For example, since the temperature drop is particularly large in the center of the support plate, it is also possible to set the temperature of only the center of the support plate to be higher in advance as described above.

As described above, in the present embodiment, when the substrate is installed in the heating furnace, the temperature drop of the support plate is suppressed to within 15%, within 10%, or within 5% of the set temperature, so that the oxide semiconductor layer 140 is rapidly heated and crystallized. By making the gradient of the temperature rise of the oxide semiconductor layer 140 during the OS annealing as steep as possible, the field-effect mobility and reliability of the semiconductor device 10 can be improved. This point will be described later.

In addition, although the example in which the OS annealing is performed after forming the OS pattern has been described in the present embodiment, the present invention is not limited to this example, and the OS annealing may be performed on the oxide semiconductor layer 140 before forming the OS pattern. Since the crystallized oxide semiconductor layer 140 is etched to form the OS pattern, dry etching is preferably used for an etching treatment.

In addition, the example in which the support plate is used as the heating medium for heating the oxide semiconductor layer 140 during the OS annealing is shown in the present embodiment. However, the present invention is not limited to this example, and the heating medium may be air. Specifically, it is also possible to heat the substrate by arranging a support member that supports the substrate in the heating furnace, supporting the substrate in a state in which most of the substrate is exposed to air, and using the heated air as a heating medium. In this case, for example, a pin-shaped member that supports the substrate from below by point contact may be used, or a member of the frame shape for supporting the edge of the substrate may be used as the support member.

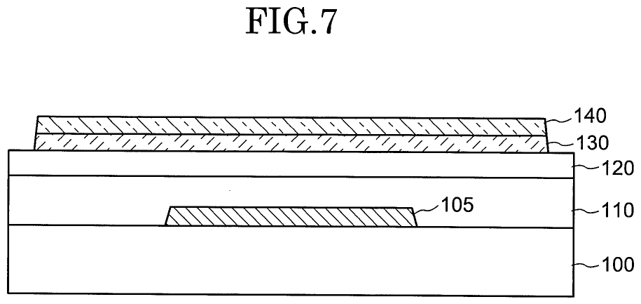

Next, as shown in FIG. 3 and FIG. 7, a pattern (AlOₓ pattern) composed of the metal oxide layer 130 is formed (step S1005 in FIG. 3). The metal oxide layer 130 is etched using the oxide semiconductor layer 140 patterned in the above-described process as a mask. Wet etching or dry etching may be used for the etching of the metal oxide layer 130. For example, dilute hydrofluoric acid (DHF) is used in wet etching. The photolithography process can be omitted by etching the metal oxide layer 130 using the oxide semiconductor layer 140 as a mask.

In addition, although the example in which the OS pattern is formed and then the AlOₓ pattern is formed using the OS pattern as a mask is shown in the present embodiment, the OS pattern and the AlOₓ pattern may be collectively formed. In this case, the oxide semiconductor layer 140 and the metal oxide layer 130 may be simultaneously etched using the same resist mask in the step S1003 in FIG. 3. However, the present invention is not limited to these examples, and the AlOₓ patterning may be omitted and the metal oxide layer 130 may be left as it is.

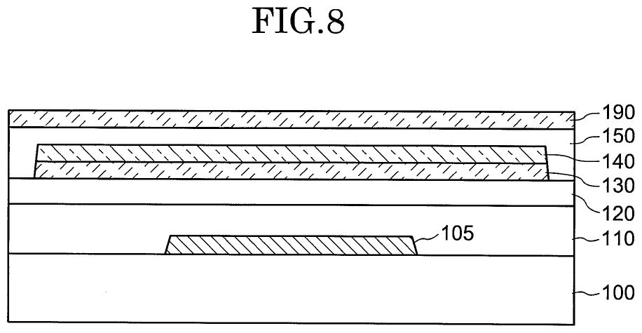

Next, as shown in FIG. 3 and FIG. 8, the gate insulating layer 150 is formed (step S1006 in FIG. 3). For example, a silicon oxide layer is formed as the gate insulating layer 150. The gate insulating layer 150 is formed by the CVD method. For example, the gate insulating layer 150 may be formed at a temperature of 350° C. or higher in order to form an insulating layer with few defects as described above as the gate insulating layer 150. For example, a thickness of the gate insulating layer 150 is 50 nm or more and 300 nm or less, 60 nm or more and 200 nm or less, or 70 nm or more and 150 nm or less.

Next, in the present embodiment, the gate insulating layer 150 is formed, and then oxygen is implanted into part of the gate insulating layer 150. Specifically, after the gate insulating layer 150 is formed, a metal oxide layer 190 is formed on the gate insulating layer 150 (step S1007 in FIG. 3). The metal oxide layer 190 is formed by the sputtering method. Oxygen is implanted into the gate insulating layer 150 by forming the metal oxide layer 190.

For example, a thickness of the metal oxide layer 190 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 190. Aluminum oxide has a high barrier property against gas. In the present embodiment, the aluminum oxide used as the metal oxide layer 190 suppresses the oxygen implanted into the gate insulating layer 150 from diffusing to the outside during the heat treatment described later.

In the case where the metal oxide layer 190 is formed by the sputtering method, a process gas used for sputtering remains in the film of the metal oxide layer 190. For example, in the case where Ar is used as the process gas for sputtering, Ar may remain in the film of the metal oxide layer 190. The remaining Ar can be detected by a SIMS (Secondary Ion Mass Spectrometry) analysis on the metal oxide layer 190.

Next, in a state where the metal oxide layer 190 is formed on the gate insulating layer 150, the heat treatment (oxidation annealing) for supplying oxygen to the oxide semiconductor layer 140 is performed (step S1008 in FIG. 3). In other words, the heat treatment (oxidation annealing) is performed on the metal oxide layer 130 and the oxide semiconductor layer 140 patterned as described above. During the process from the formation of the oxide semiconductor layer 140 to the formation of the gate insulating layer 150 on the oxide semiconductor layer 140, oxygen vacancies may occur in the top surface 141 and the side surface 143 of the oxide semiconductor layer 140. The oxidation annealing supplies oxygen released from the gate insulating layers 120 and 150 to the oxide semiconductor layer 140 and repairs the oxygen vacancies.

Since the oxygen released from the gate insulating layer 120 by the oxidation annealing is blocked by the metal oxide layer 130, oxygen is not easily supplied to the bottom surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 via the gate insulating layer 150. As a result, the oxygen released from the gate insulating layer 120 is less likely to be supplied to the bottom surface 142 of the oxide semiconductor layer 140, and is mainly supplied to the side surface 143 and the top surface 141 of the oxide semiconductor layer 140. Furthermore, the oxidation annealing supplies the oxygen released from the gate insulating layer 150 to the top surface 141 and the side surface 143 of the oxide semiconductor layer 140. The oxidation annealing may release hydrogen from the gate insulating layers 110 and 120, which is blocked by the metal oxide layer 130.

As described above, by the oxidation annealing, it is possible to supply oxygen to the top surface 141 and the side surface 143 of the oxide semiconductor layer 140 having a relatively large amount of oxygen vacancies while suppressing the supply of oxygen to the bottom surface 142 of the oxide semiconductor layer 140 having a small amount of oxygen vacancies.

Similarly, during the oxidation annealing, since the oxygen implanted into the gate insulating layer 150 is blocked by the metal oxide layer 190, the oxygen is prevented from being released into the atmosphere. Therefore, oxygen is efficiently supplied to the oxide semiconductor layer 140 by the oxidation annealing, and the oxygen vacancies are repaired.

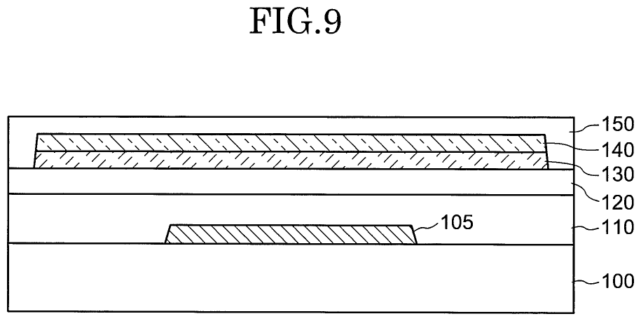

Next, as shown in FIG. 3 and FIG. 9, after the oxidation annealing, the metal oxide layer 190 is etched (removed) (step S1009 in FIG. 3). The etching of the metal oxide layer 190 may be wet etching or dry etching. For example, dilute hydrofluoric acid (DHF) is used in wet etching. The removal of the metal oxide layer 190 is performed without using a mask. In other words, the entire oxide layer 190 is removed by the etching treatment. In other words, the etching treatment removes all of the metal oxide layer 190 in a region overlapping the oxide semiconductor layer 140 formed in a certain pattern in a plan view.

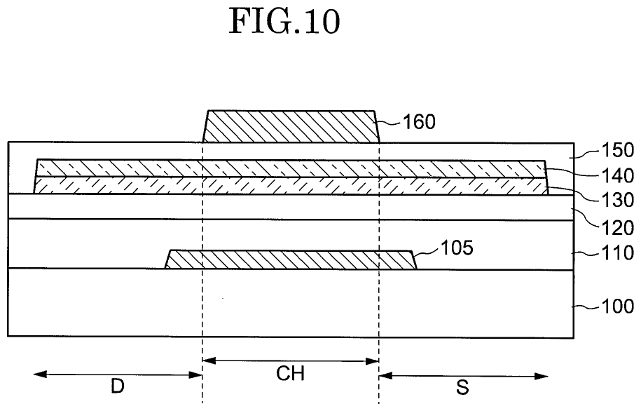

Next, as shown in FIG. 3 and FIG. 10, the gate electrode 160 is formed on the gate insulating layer 150 (step S1010 in FIG. 3). The gate electrode 160 is formed by patterning the metal layer formed by the sputtering method or an atomic layer deposition method. As described above, the gate electrode 160 is formed to be in contact with the gate insulating layer 150 exposed by removing the metal oxide layer 190.

In a state where the gate electrode 160 is formed, the resistance of the source region S and the drain region D of the oxide semiconductor layer 140 is reduced (step S1011 of FIG. 3). Specifically, an impurity is implanted into the oxide semiconductor layer 140 from the gate electrode 160 side via the gate insulating layer 150 by ion implantation. For example, argon (Ar), phosphorus (P), and boron (B) are implanted into the oxide semiconductor layer 140 by the ion implantation. Oxygen vacancies are formed in the oxide semiconductor layer 140 by the ion implantation, thereby reducing the resistance of the oxide semiconductor layer 140. Since the gate electrode 160 is arranged above the oxide semiconductor layer 140 that functions as the channel region CH, impurities are not implanted into the oxide semiconductor layer 140 in the channel region CH.

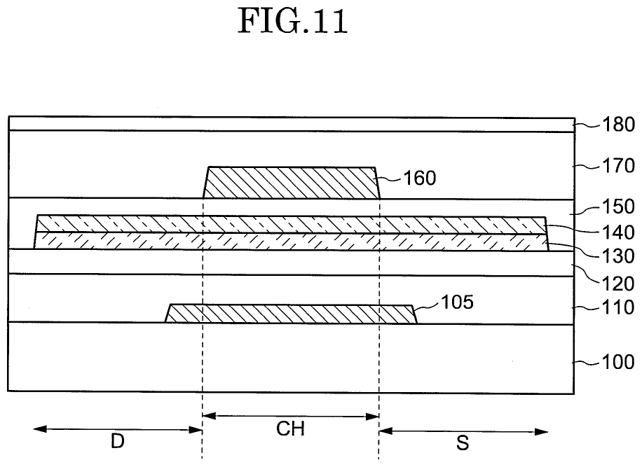

Next, as shown in FIG. 3 and FIG. 11, the insulating layers 170 and 180 are formed as interlayer films on the gate insulating layer 150 and the gate electrode 160 (step S1012 of FIG. 3). The insulating layers 170 and 180 are formed by the CVD method. For example, a silicon nitride layer is formed as the insulating layer 170, and a silicon oxide layer is formed as the insulating layer 180. The materials used for the insulating layers 170 and 180 are not limited to the above materials. In the present embodiment, a thickness of the insulating layer 170 is 50 nm or more and 500 nm or less. A thickness of the insulating layer 180 is 50 nm or more and 500 nm or less.

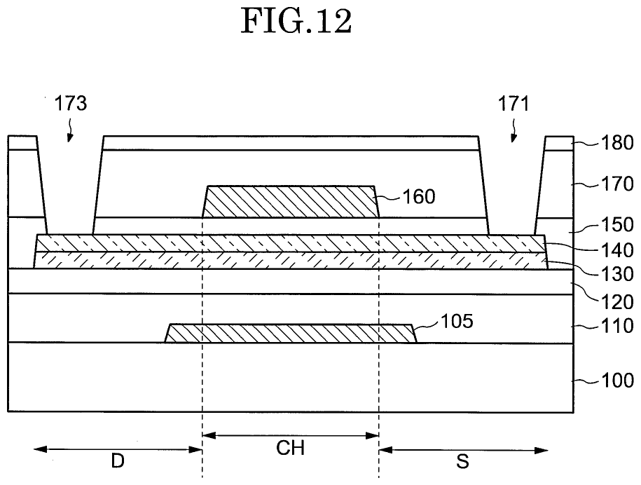

Next, as shown in FIG. 3 and FIG. 12, the openings 171 and 173 are formed in the gate insulating layer 150 and the insulating layers 170 and 180 (step S1013 in FIG. 3). The opening 171 exposes the oxide semiconductor layer 140 in the source region S. The opening 173 exposes the oxide semiconductor layer 140 in the drain region D. Forming the source/drain electrode 200 on the oxide semiconductor layer 140 and on the insulating layer 180 exposed by the openings 171 and 173 (step S1014 in FIG. 3) completes the semiconductor device 10 shown in FIG. 1.

In the semiconductor device 10 manufactured by the manufacturing method of the present embodiment, electrical characteristics having a field-effect mobility of 50 cm²/Vs or more, 55 cm²/Vs or more, or 60 cm²/Vs or more can be obtained in a range where the channel length L of the channel region CH is 2 μm or more and 4 μm or less and the channel width of the channel region CH is 2 μm or more and 25 μm or less. The “field-effect mobility” in the present embodiment is a field-effect mobility in a saturated region of the semiconductor device 10, where it means the maximal value of the field-effect mobility in a region where a potential difference (Vd) between the source electrode and the drain electrode is greater than a value (Vg-Vth) obtained by subtracting a threshold voltage (Vth) of the semiconductor device 10 from a voltage (Vg) supplied to the gate electrode.

### Second Embodiment

In the present embodiment, a semiconductor device manufactured in a method different from that of the first embodiment will be described. The structure of the semiconductor device 10 of the present embodiment is the same in appearance as the semiconductor device 10 described in the first embodiment. The present embodiment will be described focusing on differences from the first embodiment.

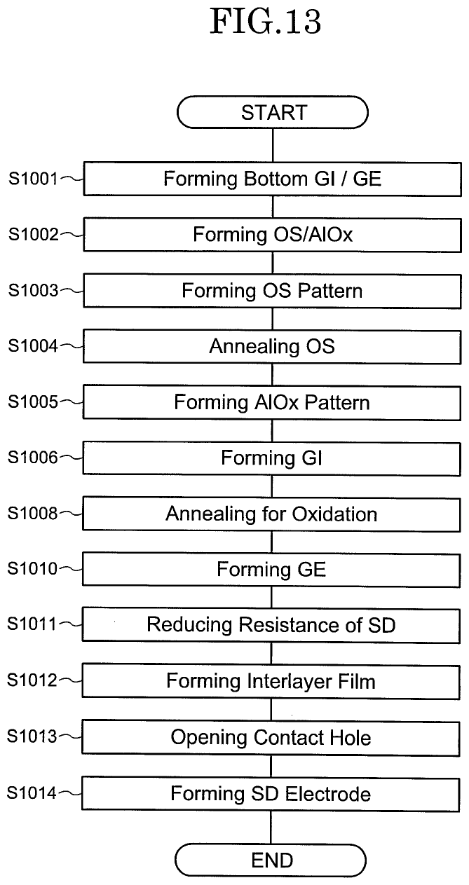

FIG. 13 is a sequence diagram showing a method for manufacturing the semiconductor device 10 according to an embodiment of the present invention. As shown in FIG. 13, in the present embodiment, two steps of step S1007 (Forming AlOₓ) and S1009 (Removing AlOₓ) shown in FIG. 3 are omitted. That is, in the present embodiment, after the gate insulating layer 150 is formed, the oxidation annealing is performed in that state. Oxygen released from the gate insulating layer 150 is supplied to the oxide semiconductor layer 140 by the oxidation annealing, and the oxygen vacancies contained in the oxide semiconductor layer 140 is repaired. Since the role of the metal oxide layer 130 in this case is similar to the first embodiment, the description thereof will be omitted.

In the semiconductor device 10 manufactured by the manufacturing method of the present embodiment, it is possible to obtain electrical characteristics having a mobility of 30 cm²/Vs or more, 35 cm²/Vs or more, or 40 cm²/Vs or more in a range where the channel length L of the channel region CH is 2 μm or more and 4 μm or less and the channel width of the channel region CH is 2 μm or more and 25 μm or less. The definition of the field-effect mobility in the present embodiment is the same as that in the first embodiment.

### Third Embodiment

In the present embodiment, a semiconductor device manufactured in a method different from that of the first embodiment will be described. A structure of a semiconductor device 10a of the present embodiment is a structure in which the metal oxide layer 130 is omitted from the semiconductor device 10 described in the first embodiment. The present embodiment will be described focusing on differences from the first embodiment, and a detailed description of the same configuration will be omitted using the same reference signs.

[Method for Manufacturing Semiconductor Device 10a]

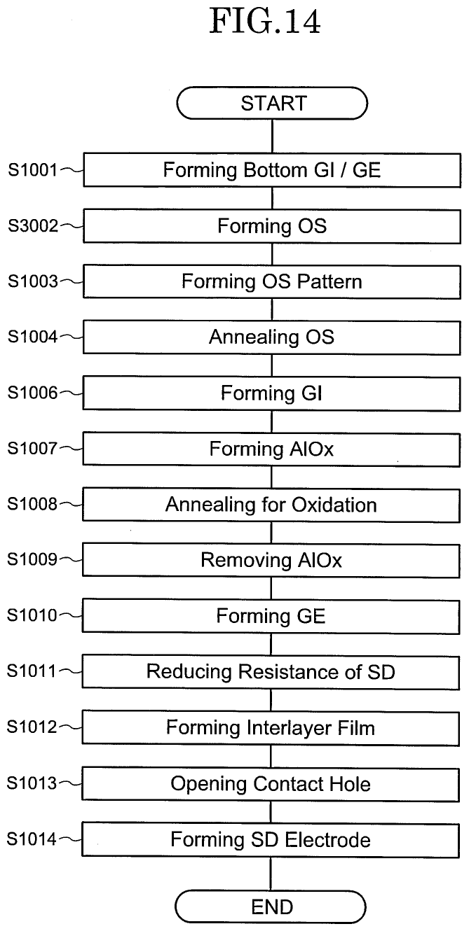

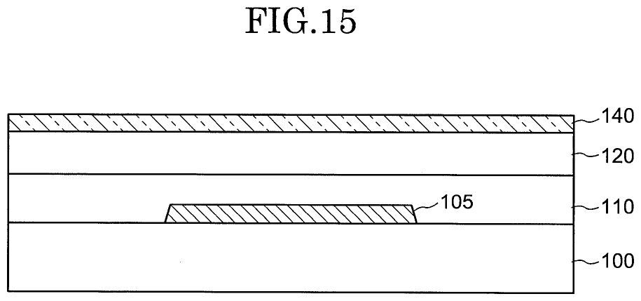

The semiconductor device 10a according to an embodiment of the present invention will be described with reference to FIG. 14 to FIG. 22. FIG. 14 is a sequence diagram showing a method for manufacturing the semiconductor device 10a according to an embodiment of the present invention. FIG. 15 to FIG. 22 are cross-sectional views showing a method for manufacturing the semiconductor device 10a according to an embodiment of the present invention.

As shown in FIG. 14 and FIG. 15, the gate electrode 105 is formed as a bottom gate on the substrate 100, and the gate insulating layers 110 and 120 are formed on the gate electrode 105 (step S1001 in FIG. 14). The process of the step S1001 is similar to the first embodiment. In the present embodiment, the gate insulating layer 120 is formed, and then the oxide semiconductor layer 140 is formed on the gate insulating layer 120 (step S3002 in FIG. 14).

In the present embodiment, the oxide semiconductor layer 140 is formed by the sputtering method. Specifically, the oxide semiconductor layer 140 is formed by sputtering using a target formed of an oxide semiconductor having crystallinity. In the present embodiment, since the formation process and configuration of the oxide semiconductor layer 140 is the same as in the first embodiment, a detailed description thereof will be omitted. For example, in the present embodiment, the oxide semiconductor layer 140 is formed by the sputtering method while being cooled such that the temperature of the object to be formed (the substrate 100 and the structure formed thereon) is 100° C. or lower, 70° C. or lower, 50° C. or lower, or 30° C. or lower.

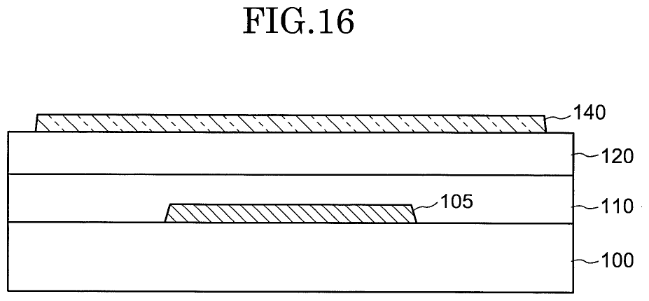

Next, as shown in FIG. 14 and FIG. 16, a pattern (OS pattern) composed of the oxide semiconductor layer 140 is formed (step S1003 in FIG. 14). After the patterning of the oxide semiconductor layer 140 is completed, the heat treatment (OS annealing) is performed on the oxide semiconductor layer 140 (step S1004 in FIG. 14). The process of the steps S1003 and S1004 is similar to the first embodiment.

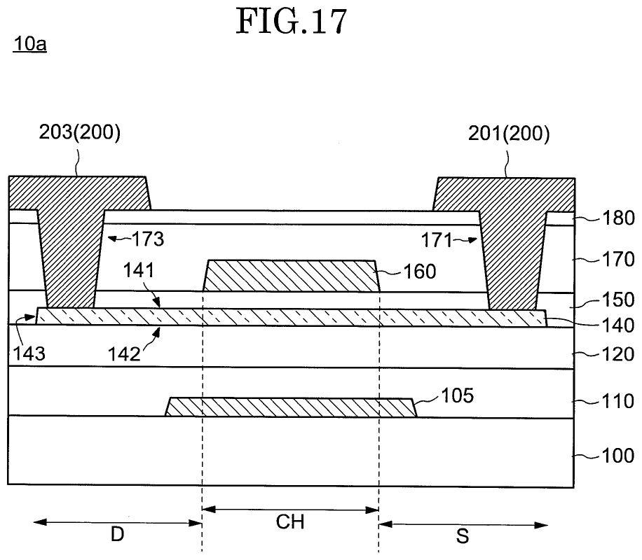

The above process completes the process up to the crystallization of the oxide semiconductor layer 140. Since the manufacturing process after the step S1004 is similar to the steps S1006 to S1014 described with reference to FIG. 3 in the first embodiment, the redundant description will be omitted. When the manufacturing process up to the step S1014 is completed, the semiconductor device 10a having the structure shown in FIG. 17 is completed. The semiconductor device 10a of the present embodiment does not include the metal oxide layer 130 below the oxide semiconductor layer 140 as compared with the semiconductor device 10 of the first embodiment. However, since the oxygen vacancies included in the oxide semiconductor layer 140 are sufficiently repaired by the process of the steps S1007 to S1009 in FIG. 14, the field-effect mobility and reliability of the semiconductor device 10a are improved.

In the semiconductor device 10a manufactured by the manufacturing method of the present embodiment, electrical characteristics having a field-effect mobility of 30 cm²/Vs or more, 35 cm²/Vs or more, or 40 cm²/Vs or more can be obtained in a range where the channel length L of the channel region CH is 2 μm or more and 4 μm or less and the channel width of the channel region CH is 2 μm or more and 25 μm or less. The definition of the field-effect mobility in the present embodiment is similar to that in the first embodiment.

### Fourth Embodiment

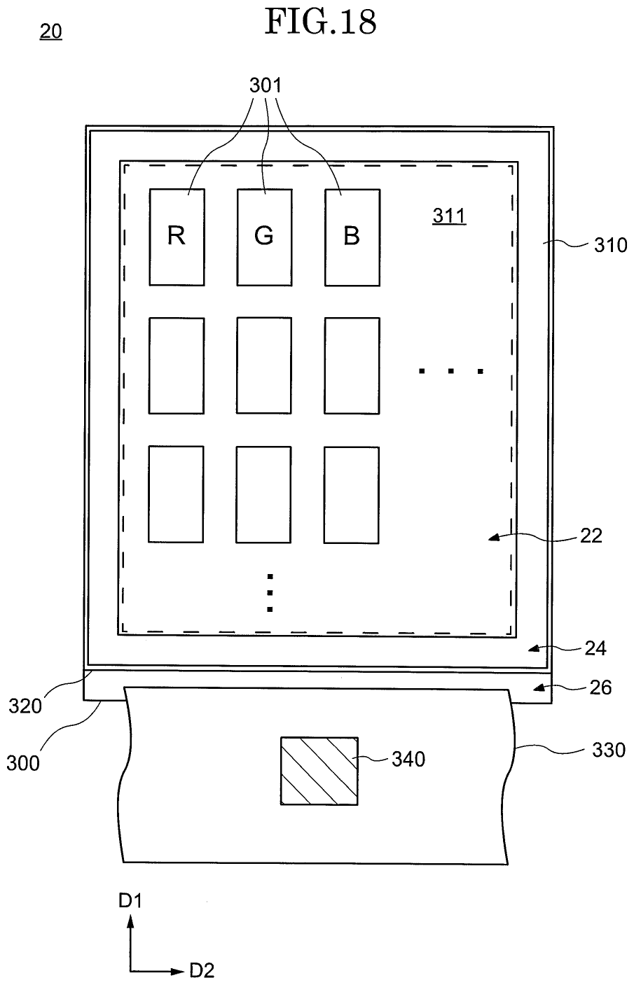

A display device using a semiconductor device according to an embodiment of the present invention will be described with reference to FIG. 18 to FIG. 22. In the embodiment described below, a configuration in which each semiconductor device described in the first to third embodiments is applied to a circuit of a liquid crystal display device will be described.

### [Outline of Display Device 20]

FIG. 18 is a plan view showing an outline of a display device 20 according to an embodiment of the present invention. As shown in FIG. 18, the display device 20 includes an array substrate 300, a seal portion 310, a counter substrate 320, and a flexible printed circuit substrate 330 (FPC 330), and an IC chip 340. The array substrate 300 and the counter substrate 320 are bonded together by the seal portion 310. A plurality of pixel circuits 301 is arranged in a matrix in a liquid crystal region 22 surrounded by the seal portion 310. The liquid crystal region 22 is a region that overlaps a liquid crystal element 311 described later in a plan view.

A seal region 24 where the seal portion 310 is arranged is a region around the liquid crystal region 22. The FPC 330 is arranged in a terminal region 26. The terminal region 26 is a region of the array substrate 300 exposed from the counter substrate 320 and is arranged on the outside the seal region 24. The outside of the seal region 24 means the outside of a region where the seal portion 310 is arranged and a region surrounded by the seal portion 310. The IC chip 340 is arranged on the FPC 330. The IC chip 340 supplies a signal for driving each pixel circuit 301.

### [Circuit Configuration of Display Device 20]

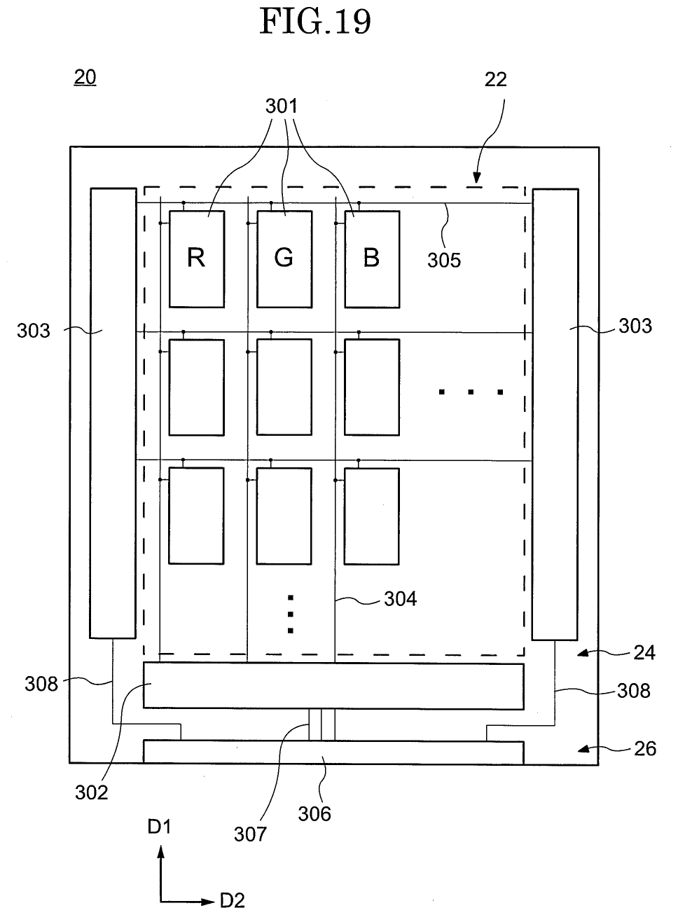

FIG. 19 is a block diagram showing a circuit configuration of the display device 20 according to an embodiment of the present invention. As shown in FIG. 19, a source driver circuit 302 is arranged at a position adjacent to the liquid crystal region 22 where the pixel circuit 301 is arranged in the direction D1 (column direction). In addition, a gate driver circuit 303 is arranged at a position adjacent to the liquid crystal region 22 in the direction D2 (row direction). The source driver circuit 302 and the gate driver circuit 303 are arranged in the seal region 24. However, the region where the source driver circuit 302 and the gate driver circuit 303 are arranged is not limited to the seal region 24, and any region may be used as long as it is outside the region where the pixel circuit 301 is arranged.

A source wiring 304 extends from the source driver circuit 302 in the direction D1 and is connected to the plurality of pixel circuits 301 arranged in the direction D1. A gate wiring 305 extends from the gate driver circuit 303 in the direction D2 and is connected to the plurality of pixel circuits 301 arranged in the direction D2.

A terminal portion 306 is arranged in the terminal region 26. The terminal portion 306 and the source driver circuit 302 are connected by a connecting wiring 307. Similarly, the terminal portion 306 and the gate driver circuit 303 are connected by a connecting wiring 308. Since the FPC 330 is connected to the terminal portion 306, an external device and the display device 20 are connected via the FPC 330, and each pixel circuit 301 arranged in the display device 20 is driven by a signal from the external device.

The semiconductor device 10 described in the first and second embodiments and the semiconductor device 10a described in the third embodiment are used as transistors included in the pixel circuit 301, the source driver circuit 302, and the gate driver circuit 303.

### [Pixel Circuit 301 of Display Device 20]

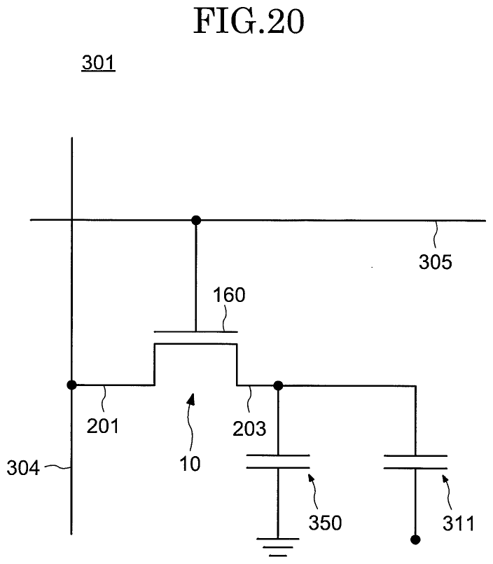

FIG. 20 is a circuit diagram showing the pixel circuit 301 of the display device 20 according to an embodiment of the present invention. As shown in FIG. 20, the pixel circuit 301 includes elements such as the semiconductor device 10, a storage capacitor 350, and the liquid crystal element 311. In addition, although the example in which the semiconductor device 10 according to the first embodiment and the second embodiment is used is shown in FIG. 20, the semiconductor device 10a according to the third embodiment may be used.

The semiconductor device 10 includes the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, for convenience of explanation, the electrode indicated by reference sign “201” is referred to as the source electrode, and the electrode indicated by reference sign “203” is referred to as the drain electrode, but the electrode indicated by reference sign “201” may function as the drain electrode, and the electrode indicated by reference sign “203” may function as the source electrode.

### [Cross-Sectional Structure of Display Device 20]

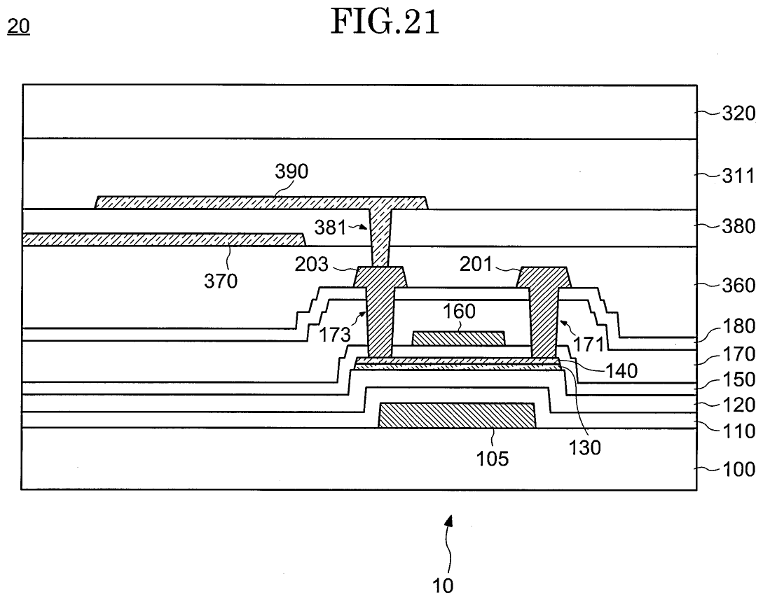

FIG. 21 is a cross-sectional view of the display device 20 according to an embodiment of the present invention. As shown in FIG. 21, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is similar to that of the semiconductor device 10 shown in FIG. 1, a detailed description thereof will be omitted.

An insulating layer 360 is arranged on the source electrode 201 and the drain electrode 203. A common electrode 370 commonly arranged in a plurality of pixels is arranged on the insulating layer 360. An insulating layer 380 is arranged on the common electrode 370. An opening 381 is arranged in the insulating layers 360 and 380. A pixel electrode 390 is arranged in the insulating layer 380 and inside the opening 381. The pixel electrode 390 is connected to the drain electrode 203.

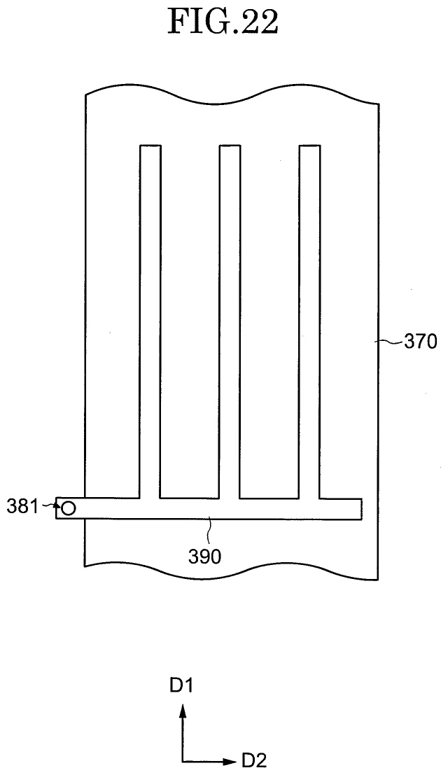

FIG. 22 is a plan view of the pixel electrode 390 and the common electrode 370 of the display device 20 according to an embodiment of the present invention. As shown in FIG. 22, the common electrode 370 has an overlapping region that overlaps the pixel electrode 390 in a plan view and a non-overlapping region that does not overlap the pixel electrode 390. Supplying a voltage between the pixel electrode 390 and the common electrode 370 creates a transverse electric field from the pixel electrode 390 in the overlapping region towards the common electrode 370 in the non-overlapping region. Liquid crystal molecules contained in the liquid crystal element 311 are operated by the transverse electric field, so that the gradation of the pixel is determined.

### Fifth Embodiment

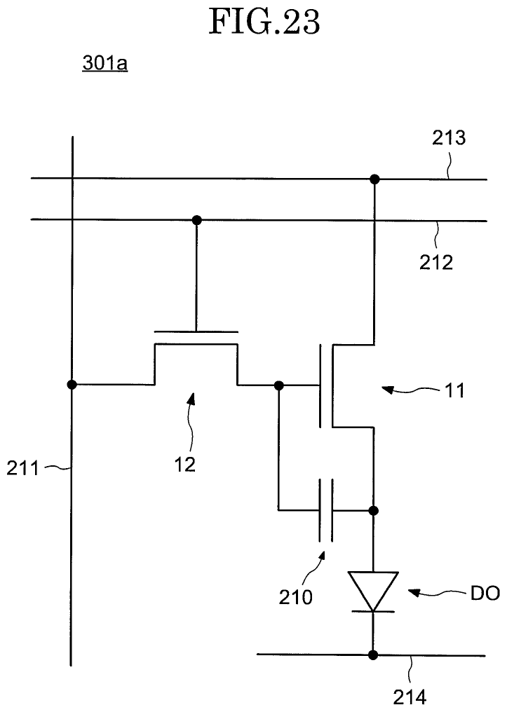

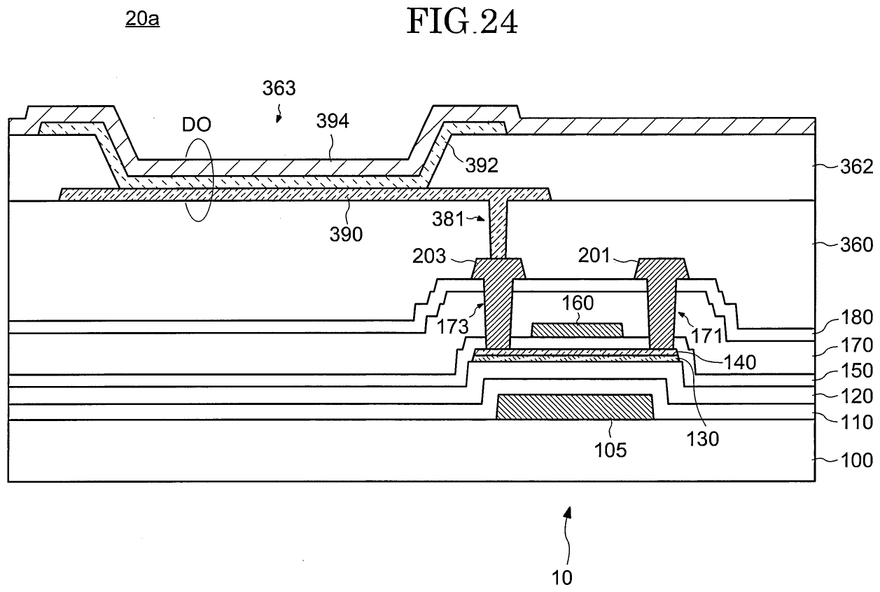

A display device using a semiconductor device according to an embodiment of the present invention will be described with reference to FIG. 23 and FIG. 24. In the embodiments described below, a configuration in which the semiconductor devices described in the first to third embodiments are applied to a circuit of an organic EL display device will be described. Since an outline of a display device 20a and the circuit configuration are similar to those shown in FIG. 18 and FIG. 19, a description will be omitted.

### [Pixel Circuit 301 of Display Device 20]

FIG. 23 is a circuit diagram showing a pixel circuit 301a of the display device 20a according to an embodiment of the present invention. As shown in FIG. 23, the pixel circuit 301a includes elements such as a drive transistor 11, a select transistor 12, a storage capacitor 210, and a light-emitting element DO. In addition, although the example in which the semiconductor device 10 according to the first embodiment and the second embodiment is used is shown in FIG. 23, the semiconductor device 10a according to the third embodiment may be used.

The drive transistor 11 and the select transistor 12 have a similar configuration as the semiconductor device 10. A source electrode of the select transistor 12 is connected to a signal line 211, and a gate electrode of the select transistor 12 is connected to a gate line 212. A source electrode of the drive transistor 11 is connected to an anode power line 213, and a drain electrode of the drive transistor 11 is connected to one end of the light-emitting element DO. The other end of the light-emitting element DO is connected to a cathode power line 214. A gate electrode of the drive transistor 11 is connected to the drain electrode of the select transistor 12. The storage capacitor 210 is connected to the gate electrode and the drain electrode of the drive transistor 11. A gradation signal that determines the emission intensity of the light-emitting element DO is supplied to the signal line 211. A signal for selecting a pixel row to which the gradation signal is written is supplied to the gate line 212.

### [Cross-Sectional Structure of Display Device 20]

FIG. 24 is a cross-sectional view of the display device 20a according to an embodiment of the present invention. A configuration of the display device 20a shown in FIG. 24 is similar to that of the display device 20 shown in FIG. 21, but the structure above the insulating layer 360 of the display device 20a shown in FIG. 24 is different from the structure above the insulating layer 360 of the display device 20 shown in FIG. 21. Hereinafter, among the configurations of the display device 20a shown in FIG. 24, similar configurations as those of the display device 20 shown in FIG. 21 will be omitted, and differences between the two will be described.

As shown in FIG. 24, the display device 20a has the pixel electrode 390, a light-emitting layer 392, and a common electrode 394 above the insulating layer 360. The pixel electrode 390, the light-emitting layer 392, and the common electrode 394 constitute the light-emitting element DO. The pixel electrode 390 is arranged on the insulating layer 360 and inside the opening 381. An insulating layer 362 is arranged on the pixel electrode 390. An opening 363 is arranged in the insulating layer 362. The opening 363 corresponds to a light-emitting region. That is, the insulating layer 362 defines a pixel. The light-emitting layer 392 and the common electrode 394 are arranged on the pixel electrode 390 exposed by the opening 363. The pixel electrode 390 and the light-emitting layer 392 are arranged for each pixel. On the other hand, the common electrode 394 is arranged in common to a plurality of pixels. The light-emitting layer 392 is made of a material that varies depending on the display color of the pixel.

In the fourth embodiments and fifth embodiment, although the configuration in which the semiconductor device described in the first embodiment to the third embodiment is applied to the liquid crystal display device and the organic EL display device has been exemplified, each semiconductor device may be applied to a display device (for example, a self-luminous display device or an electronic paper display device other than the organic EL display device) other than those display devices. In addition, the above-described semiconductor device can be applied from a medium-sized display device to a large-sized display device without any particular limitation.

### EXAMPLES

The results of a verification experiment performed on the semiconductor device 10 manufactured by the above-described method according to the second embodiment will be described below.

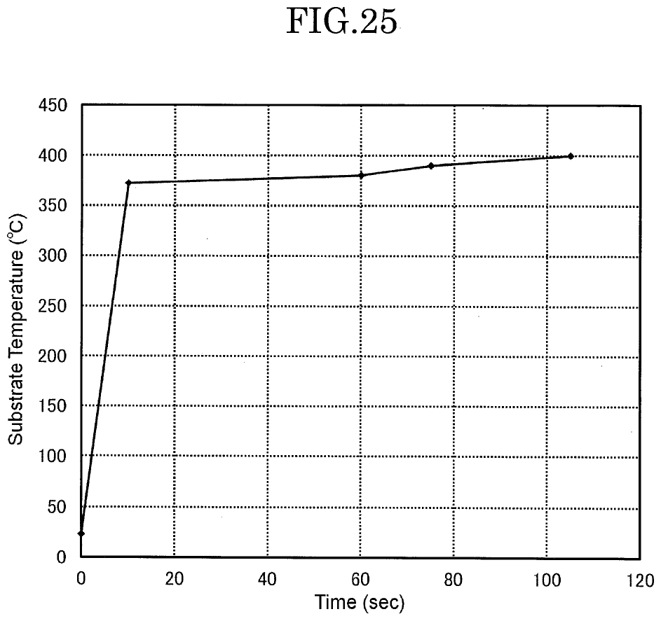

FIG. 25 is a graph showing a result of investigating the follow-up of the substrate temperature to the support plate arranged in the heating furnace. The graph shown in FIG. 25 is a plot of the temperature measured by a thermocouple arranged on a surface to be formed (a surface on which a structure is formed) of a glass substrate placed on a support plate against time. The measured temperature is plotted against time. The thermocouple was placed substantially at the center of the surface to be formed of the glass substrate. The set temperature of the support plate is 400° C. A thickness of the glass substrate is 0.5 mm.

According to the results shown in FIG. 25, it is understood that the temperature of the surface to be formed of the glass substrate placed on the support plate substantially follows the temperature of the support plate. Specifically, the surface to be formed reaches 370° C. in about 10 seconds after the glass substrate is placed on the support plate. After that, the temperature of the surface to be formed gradually increases, and after about 100 seconds, the temperature reaches the set temperature of 400° C.

In the present verification experiment, the glass substrate is placed on the support plate, which slightly reduces the temperature of the support plate heated to 400° C. However, since the temperature drop of the support plate is suppressed to within 10% (that is, the temperature of the support plate is maintained at 360° C. or higher at the time when the substrate is installed), the temperature of the surface to be formed of the glass substrate can be rapidly increased to 370° C. The reason why the temperature of the surface to be formed of the glass substrate gradually increased to 400° C. in FIG. 25 is considered to be that it took time for the temperature of the support plate temporarily decreased to around 370° C. to increase to 400° C. after the glass substrate was installed.

As described above, the temperature of the surface to be formed of the glass substrate placed on the support plate rapidly increases following the temperature of the support plate. That is, it can be said that the temperature of the oxide semiconductor layer 140 formed on the substrate 100 is rapidly heated following the temperature of the support plate.

Next, when the substrate is installed in the heating furnace in the OS annealing, the effect on the semiconductor device of the present embodiment will be described in the case where the temperature drop of the support plate is suppressed to within 10% of the set temperature and the case where the temperature drop is not suppressed to within 10%.

### [Electrical Characteristics of Semiconductor Device 10]

Electrical characteristics of the semiconductor device having the same structure as the semiconductor device 10 according to the second embodiment will be exemplified, and the effect of the temperature rise during the OS annealing will be described.

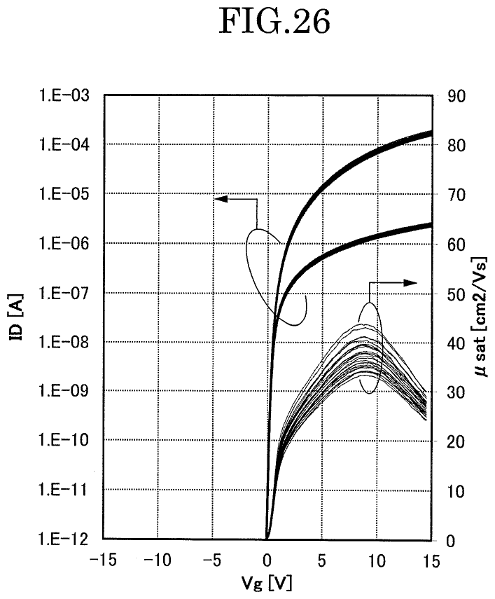

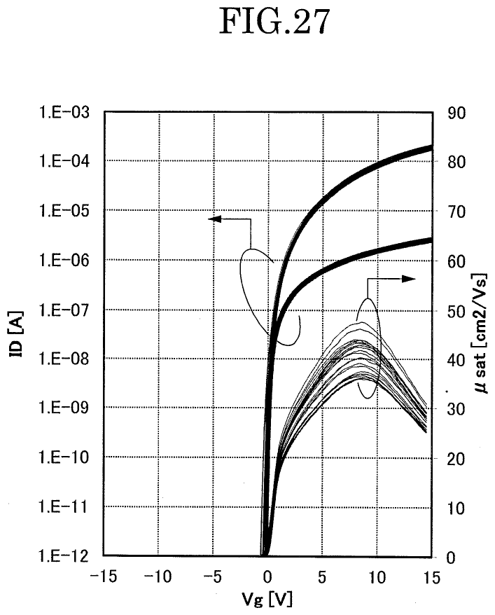

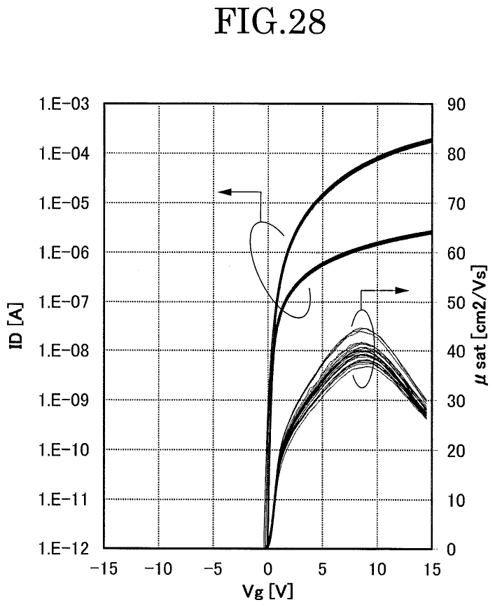

FIG. 26 to FIG. 28 are diagrams showing electric characteristics (Id-Vg characteristics) of the semiconductor device in the case where the OS annealing is performed under different conditions. Specifically, FIG. 26 shows a reference embodiment in which the present invention is not applied during the OS annealing. FIG. 27 and FIG. 28 show examples in which the temperature drop of the support plate is suppressed to within 10% during the OS annealing. In addition, the result of FIG. 27 is a result obtained when the heating atmosphere is a dry atmosphere. The result of FIG. 28 is a result when the heating atmosphere is a wet atmosphere.

The measurement conditions of the electrical characteristics shown in FIG. 26 to FIG. 28 are as follows.
Size of the channel region CH: W/L=4.5 μm/3.0 μm
Source/drain voltage: 0.1 V, 10 V
Gate voltage: −15 V to +15 V
Measurement environment: room temperature, dark room
Number of measurement points: 26

In addition, the gate voltage is applied to both the gate electrode 105 and the gate electrode 160 in the semiconductor device of the structure shown in FIG. 2. In other words, the results shown in FIG. 26 to FIG. 28 are the results obtained when the semiconductor device is dual-gate driven.

As indicated by arrows in the graphs of FIG. 26 to FIG. 28, the vertical axis corresponding to a drain current (ID) is shown on the left side of the graph, and the vertical axis corresponding to a field-effect mobility (μsat) calculated from the drain current is shown on the right side of the graph. Among the two drain currents, the larger value is a graph when the source/drain voltage is 10 V, and a smaller value is a graph when the source/drain voltage is 0.1 V. FIG. 26 to FIG. 28 show a so-called normally-off characteristic in which the drain current Id starts to flow at a voltage at which the gate voltage Vg is slightly higher than 0 V.

In the graphs shown in FIG. 26 to FIG. 28, the average values of the field-effect mobilities calculated from the drain currents are 37.6 cm²/Vs, 40.5 cm²/Vs, and 39.9 cm²/Vs, respectively. That is, compared with the reference example shown in FIG. 26, in the examples shown in FIG. 27 and FIG. 28, the value of the field-effect mobility was improved by about 10%. As described above, it was found that the difference in whether or not the temperature drop of the support plate at the time of the substrate installation is suppressed to within 10% during the OS annealing significantly affects the magnitude of the field-effect mobility. In addition, from the results shown in FIG. 27 and FIG. 28, it was found that when the heating atmosphere is a wet atmosphere, the variation in the field-effect mobility can be reduced as compared with the case of the dry atmosphere.

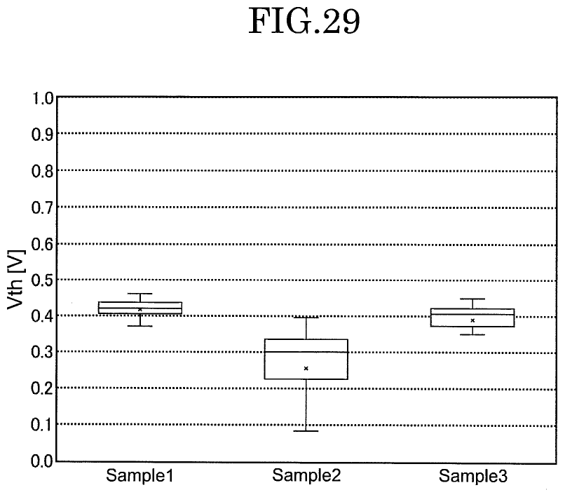

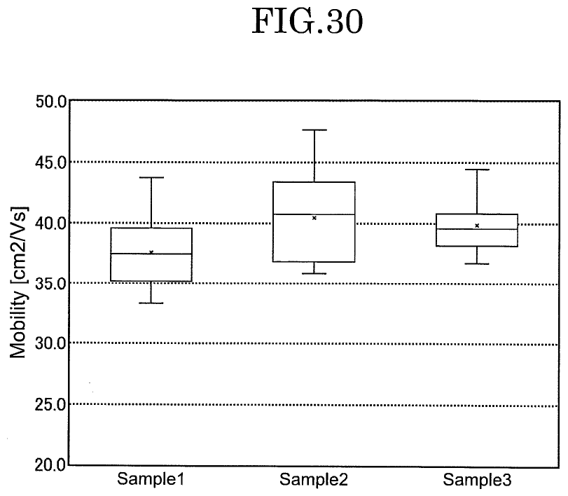

FIG. 29 to FIG. 30 are diagrams showing electrical characteristics of the semiconductor device when the OS annealing is performed under different conditions. In FIG. 29 to FIG. 30, “Sample 1” indicates a reference example (an example of the same condition as the graph shown in FIG. 26) to which the present invention is not applied during the OS annealing. “Sample 2” represents an embodiment in which the OS annealing is performed in a dry atmosphere, and the temperature drop of the support plate is suppressed to within 10% during the OS annealing (the same condition as the graph shown in FIG. 27). “Sample 3” shows an embodiment in which the OS annealing is performed in a wet atmosphere, and the temperature drop of the support plate is suppressed to within 10% during the OS annealing (the same condition as the graph shown in FIG. 28). FIG. 29 to FIG. 30 are so-called “box plots”.

FIG. 29 is a graph showing the effect of the temperature drop of the support plate during the OS annealing on the threshold (Vth) of the semiconductor device. As shown in FIG. 29, a large change in the threshold value was not observed between Sample 1 and Sample 3, but a decrease in the threshold value was observed in Sample 2. Specifically, the average values of the threshold values of Sample 1 to Sample 3 were 0.42 V, 0.26 V, and 0.39 V, respectively.

FIG. 30 is a graph showing the effect of the temperature drop of the support plate during the OS annealing on the field-effect mobility (Mobility) of the semiconductor device. As described above, it was confirmed that the field-effect mobility was improved in Sample 2 and Sample 3 as compared with Sample 1. In addition, from the results of Sample 2 and Sample 3, it was confirmed that a moist atmosphere in the heating furnace during the OS annealing was effective in reducing the variation in the field-effect mobility.

As described above, it was confirmed that the field-effect mobility was improved when the temperature drop of the support plate was suppressed to within 10% during the OS annealing.

Each of the embodiments described above as an embodiment of the present invention can be appropriately combined and implemented as long as no contradiction is caused. In addition, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A method for manufacturing a semiconductor device, the method comprising steps of:
forming an oxide semiconductor layer on a substrate by a sputtering method;
performing a first heat treatment on the oxide semiconductor layer after placing the substrate on which the oxide semiconductor layer is formed in a heating furnace having a heating medium maintained at a preset temperature;
forming a gate insulating layer on the oxide semiconductor layer after the first heat treatment; and
forming a gate electrode on the gate insulating layer, wherein
when the substrate is installed in the heating furnace, a temperature drop of the heating medium is kept within 15% of the preset temperature.

2. The method according to claim 1, wherein
a first metal oxide layer mainly composed of aluminum is formed on the substrate prior to forming the oxide semiconductor layer; and
the oxide semiconductor layer is formed on and in contact with the first metal oxide layer.

3. The method according to claim 2, wherein
a second metal oxide layer mainly composed of aluminum is formed on the gate insulating layer after forming the gate insulating layer;
a second heat treatment is performed on the gate insulating layer with the second metal oxide layer on the gate insulating layer;
the second metal oxide layer is removed after the second heat treatment; and
the gate electrode is formed on the gate insulating layer after removing the second metal oxide layer.

4. The method according to claim 1, wherein
a metal oxide layer mainly composed of aluminum is formed on the gate insulating layer after forming the gate insulating layer;
a second heat treatment is performed on the gate insulating layer with the metal oxide layer on the gate insulating layer;
the metal oxide layer is removed after the second heat treatment; and
the gate electrode is formed on the gate insulating layer after removing the metal oxide layer.

5. The method according to claim 1, wherein
the preset temperature is 400° C. or more and 450° C. or less.

6. The method according to claim 1, wherein
sputtering is performed while cooling the substrate when forming the oxide semiconductor layer by the sputtering method.

7. The method according to claim 6, wherein
a difference between a temperature for forming the oxide semiconductor layer and a temperature for performing the first heat treatment is 350° C. or more.

8. The method according to claim 7, wherein
a temperature for forming the oxide semiconductor layer is 50° C. or less, and
a temperature for performing the first heat treatment is 400° C. or more.

9. The method according to claim 1, wherein
the first heat treatment is performed after patterning the oxide semiconductor layer.

10. The method according to claim 1, wherein
the oxide semiconductor layer includes two or more metals including indium, and
a ratio of indium in the two or more metals is 50% or more.

11. A method for manufacturing a semiconductor device, the method comprising steps of:
forming a gate electrode on a substrate;
forming a gate insulating layer on the gate electrode;
forming an oxide semiconductor layer on the gate insulating layer by a sputtering method; and
performing a first heat treatment on the oxide semiconductor layer after placing the substrate on which the oxide semiconductor layer is formed in a heating furnace having a heating medium maintained at a preset temperature; wherein
when the substrate is installed in the heating furnace, a temperature drop of the heating medium is kept within 15% of the set temperature.

12. The method according to claim 11, wherein
a first metal oxide layer mainly composed of aluminum is formed on the gate insulating layer prior to forming the oxide semiconductor layer; and
the oxide semiconductor layer is formed on and in contact with the first metal oxide layer.

13. The method according to claim 12, wherein
an insulating layer is formed on the oxide semiconductor layer after performing the first heat treatment on the oxide semiconductor layer;
a second metal oxide layer mainly composed of aluminum is formed on the insulating layer after;
a second heat treatment is performed on the insulating layer with the second metal oxide layer on the insulating layer; and
the second metal oxide layer is removed after the second heat treatment.

14. The method according to claim 11, wherein
an insulating layer is formed on the oxide semiconductor layer after performing the first heat treatment on the oxide semiconductor layer;
a metal oxide layer mainly composed of aluminum is formed on the insulating layer;
a second heat treatment is performed on the insulating layer with the metal oxide layer on the insulating layer; and
the metal oxide layer is removed after the second heat treatment.

15. The method according to claim 11, wherein
the preset temperature is 400° C. or more and 450° C. or less.

16. The method according to claim 11, wherein
sputtering is performed while cooling the substrate when forming the oxide semiconductor layer by the sputtering method.

17. The method according to claim 16, wherein
the difference between a temperature for forming the oxide semiconductor layer and a temperature for performing the first heat treatment is 350° C. or more.

18. The method according to claim 17, wherein
a temperature for forming the oxide semiconductor layer is 50° C. or less, and
a temperature for performing the first heat treatment is 400° C. or more.

19. The method according to claim 11, wherein
the first heat treatment is performed after patterning the oxide semiconductor layer.

20. The method according to claim 11, wherein
the oxide semiconductor layer includes two or more metals including indium, and
a ratio of indium in the two or more metals is 50% or more.
